(19) United States
(12) Patent Application Publication
(10) Pub. No.: US 2009/0232173 A1
(43) Pub. Date: Sep. 17, 2009

(54) Optical semiconductor apparatus

(75) Inventor: Goji Nakagawa, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/292,469

(22) Filed: Nov. 19, 2008

(30) Foreign Application Priority Data
Mar. 14, 2008 (JP) 2008-066288

(51) Int. Cl. H01S 3/04; H01S 5/00

(52) U.S. Cl. 372/34; 372/50.23

(57) ABSTRACT

An optical semiconductor apparatus includes: an optical semiconductor element that outputs light; a lens that transmits light output from the optical semiconductor element; and a support member that is integrally formed and includes a first support supporting the optical semiconductor element, a second support supporting the lens, and an intermediate portion through which the first support and the second support are integrated.

### CROSS-REFERENCE TO RELATED APPLICATIONS

This application is based upon and claims the benefit of priority from the prior Japanese Patent Application No. 2008-066288, filed on Mar. 14, 2008, the entire contents of which are incorporated herein by reference.

### BACKGROUND OF THE INVENTION

1. Field of the Invention

The present invention relates to an optical semiconductor apparatus that outputs light.

2. Description of the Related Art

In recent years, accompanying the increase in communication needs brought about by broadband services, advances in optical communication networks covering longer distances and having greater capacities have been made and the development of high-speed, large-capacity wavelength division multiplexing (WDM) is progressing. WDM is a transmission scheme in which optical signals of differing wavelengths are transmitted simultaneously in a single optical fiber. Meanwhile, with the rapid expansion of the Internet and the rise in large-volume content, a high-speed, high capacity optical communications network that further affords flexibility is needed.

Optical packet switching is a focus of technology for building such optical communications networks. Optical packet switching is the exchange of communication information packets entirely in the optical domain. In comparing optical packet switching to switching involving the conversion of an optical signal into an electrical signal, optical packet switching is not subject to electrical processing rate limitations; thereby enabling processing that maintains the optical propagation velocity. Hence, through the utilization of optical packet switching, high speed, high volume transmission becomes possible.

When optically switching optical signals in packet units, a gate switch that switches the optical signals between ON and OFF is employed. Gate switches that switch optical signals between ON and OFF under electrical control primarily include those that utilize the electroabsorption effect to vary absorption and those that vary the gain of the switch according to the driving current supplied to a semiconductor optical amplifier (SOA).

Electroabsorption-type gate switches have the disadvantage of a large loss even in a transmission state. On the other hand, SOAs are switches that vary the gain of the switch according to the driving current supplied. As light is amplified and output when the gate is ON, SOAs not only function as optical gates switching light ON and OFF, but further have a combined function of optical amplification.

Hence, SOAs have attracted attention as optical elements that perform high-speed switching with low optical signal loss. Further, the extinction ratio at gate ON/OFF is high for SOAs and amplification enables reduction of optical loss. As SOAs are optical elements formed by semiconductors, semiconductor integrated technology realizes the advantages of low cost and compact size.

The extinction ratio at gate ON/OFF is the ratio of the average optical intensity of a signal “1” “0” when the gate is ON and the average optical intensity of a signal “1” “0” when the gate is OFF. The greater the extinction ratio, the more clearly the ON/OFF state of the gate can be distinguished; therefore, interference by signals to other ports (crosstalk) is reduced, thereby reducing the encoding error rate. Optical semiconductor elements emitting light, such as SOAs and laser diodes (LDs), require driving currents of several hundred milliamperes.

Hence, power consumption of optical semiconductor elements ranges between 0.5 watts to 1 watt. When a SOA array formed by plural SOAs is employed, power consumption reaches up to several watts. Further, for optical semiconductor elements, output power characteristics with respect to power consumption decreases as temperature decreases. Therefore, to maintain the optical semiconductor element at a constant temperature, Peltier element is employed to adjust the temperature of the optical semiconductor element, as disclosed in Japanese Patent Application Laid-Open Publication No. H7-287130.

FIG. 15 is a front cross-sectional view of a conventional optical semiconductor apparatus. FIG. 16 is a top view of an optical semiconductor element depicted in FIG. 15. A conventional optical semiconductor apparatus 150 includes an LD array 151 having plural LDs. Each of the LDs of the LD array 151 outputs light according to the driving current supplied. The LD array 151 is provided on a Peltier element 153 through a first stem 152.

A lens 154 transmits lights emitted from the LD array 151. The lens 154 is provided on the Peltier element 153 through a second stem 155. When the Peltier element 153 controls the temperature, the size of the Peltier element 153 varies, thereby causing deviation in the relative positions of the light emitted from the LD array 151 and the lens 154 and hence, provision of both the LD array 151 and the lens 154 on the Peltier element 153 prevents the occurrence of optical coupling loss.

Concerning the assembly of the optical semiconductor apparatus 150, the stem 152 and the stem 155 that are precision-manufactured by machined processing are arranged on the Peltier element 153 and fixed by soldering. On the stem 152, the LD array 151 is arranged and on the stem 155, the lens 154 is arranged, where the position of the optical axis of the light emitted from each of the LDs of the LD array and a central portion of the lens 154 substantially coincide.

While light is being emitted from the LD array 151, the position of the lens 154 is determined such that the light transmitted by the lens 154 becomes collimated and the lens 154 is fixed on the stem 155 by laser welding or soldering. Thereafter, the position of an optical fiber array 156 is adjusted such that the light transmitted by the lens 154 is coupled with the optical fiber array 156 at a maximum rate.

With the conventional technology above, a problem arises in that the relative positions of the part supporting the LD array 151 of the stem 152 and the part supporting the lens 154 of the stem 155 are determined by the precision of the assembly of the stems 152 and 155 with respect to the Peltier element 153 and hence, the respective positions of the LD array 151 and the lens 154 cannot be adjusted with high precision.

Specifically, as the stem 152 and the stem 155 are fixed on the Peltier element 153 by soldering or the like, the distance from the Peltier element 153, the angle with respect to the Peltier element 153, etc. cannot be adjusted with high precision. Hence, the position of the lens 154 with respect to each of the lights emitted from the LD array 151 deviates in the direction of the x-axis, and/or is tilted about the x-axis and/or the z-axis. Thus, the light emitted from the LD array 151 cannot be aligned with the ends of the optical fiber array 156 with high precision and the transmission characteristics of the light output from the optical fiber array 156 degrades.

In particular, as depicted in FIG. 16, when the LD array 151 is employed, the coupling position of light 162 emitted from each of the LDs of the LD array 151 deviates in the direction of the x-axis as indicated by the reference numeral 161 in FIG. 16. Hence, with precision, the light 162 emitted from the LD array 151 cannot be coupled with the ends of the optical fibers of the optical fiber array 156 aligned in the direction of the y-axis. As a result, respective transmission characteristics of the channels of the optical fiber array 156 become non-uniform.

### SUMMARY OF THE INVENTION

It is an object of the present invention to at least solve the above problem in the conventional technologies.

An optical semiconductor apparatus according to one aspect of the present invention includes: an optical semiconductor element that outputs light; a lens that transmits light output from the optical semiconductor element; and a support member that is integrally formed and includes a first support supporting the optical semiconductor element, a second support supporting the lens, and an intermediate portion through which the first support and the second support are integrated.

The other objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a front cross-sectional view of an optical semiconductor apparatus according to a first embodiment;

FIG. 2 is a top view of an optical semiconductor element and a stem depicted in FIG. 1;

FIG. 3 is a top view of a modified example of the optical semiconductor element depicted in FIGS. 1 and 2;

FIG. 4 is a front cross-sectional view of the optical semiconductor apparatus according to a second embodiment;

FIG. 5 is a front view and a side view of a fixing ring depicted in FIG. 4;

FIG. 6 is a front cross-sectional view of the optical semiconductor apparatus according to a third embodiment;

FIG. 7 is a front cross-sectional view of the optical semiconductor apparatus according to a fourth embodiment;

FIG. 8 is a front cross-sectional view of the optical semiconductor apparatus according to a fifth embodiment;

FIG. 9 is a top view of the optical semiconductor element and the stem depicted in FIG. 8;

FIG. 10 is a front cross-sectional view of the optical semiconductor apparatus according to a sixth embodiment;

FIG. 11 is a top view of the optical semiconductor element and the stem depicted in FIG. 10;

FIG. 12 is a top view of a modified example of the optical semiconductor element depicted in FIGS. 10 and 11;

FIG. 13 is a front cross-sectional view of the optical semiconductor apparatus according to a seventh embodiment;

FIG. 14 is a front view and a side view of an optical semiconductor element and a stem depicted in FIG. 13;

FIG. 15 is a front cross-sectional view of a conventional optical semiconductor apparatus; and

FIG. 16 is a top view of an optical semiconductor element depicted in FIG. 15.

### DETAILED DESCRIPTION OF THE PREFERRED EMBODIMENTS

Referring to the accompanying drawings, exemplary embodiments according to the present invention are explained in detail below.

With reference to the accompanying drawings, exemplary embodiments of an optical semiconductor apparatus according to the present invention are explained in detail below.

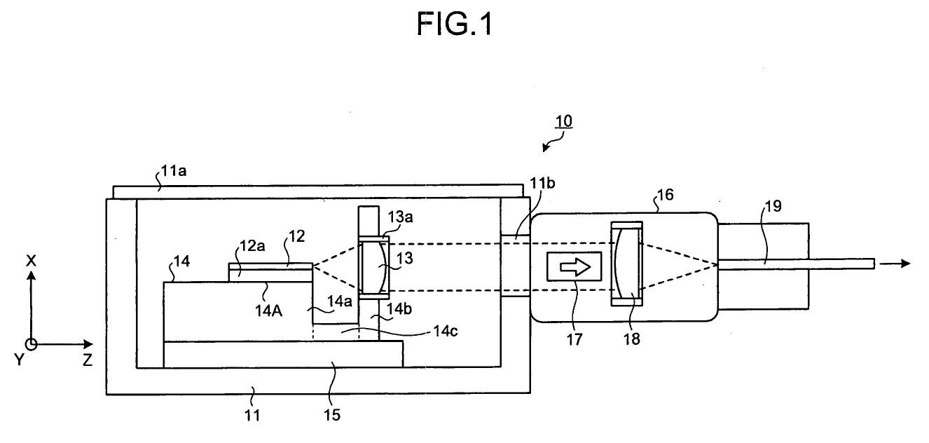

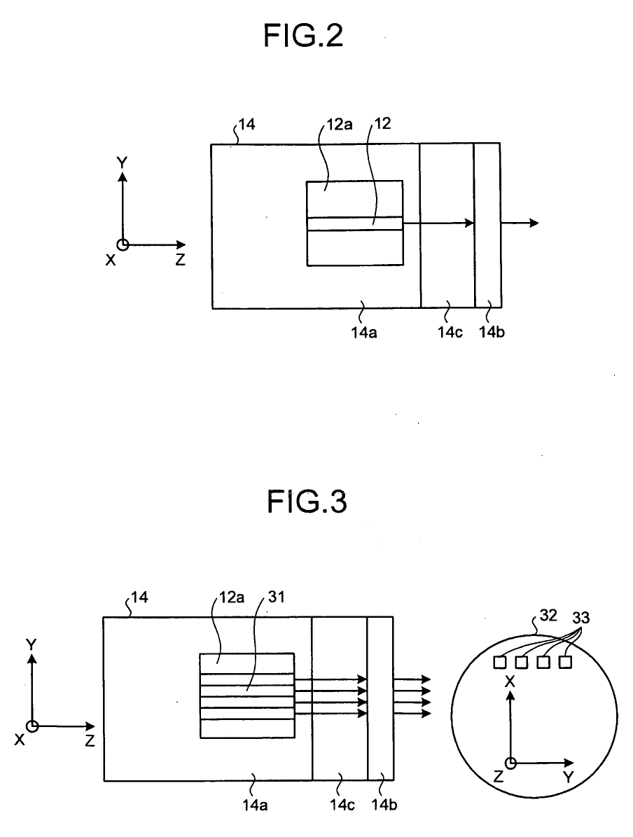

FIG. 1 is a front cross-sectional view of an optical semiconductor apparatus according to a first embodiment. FIG. 2 is a top view of an optical semiconductor element and a stem depicted in FIG. 1. In the drawings, the z-axis indicates the optical propagation direction. The zx-plane indicates a front aspect of the optical semiconductor apparatus. The zy-plane indicates an upper aspect of the optical semiconductor apparatus. As depicted in FIG. 1, an optical semiconductor apparatus 10 according to the first embodiment includes a casing 11, an LD 12, an element carrier 12a, a lens 13, a stem 14, a Peltier element 15, and an output unit 16.

The optical semiconductor apparatus 10 outputs light according to the driving current supplied. An opening 11b for outputting light is provided in the casing 11. Reference numeral 11a indicates a cover of the casing 11. The LD 12, the element carrier 12a, the lens 13, the stem 14, the Peltier element 15, and the output unit 16 are provided inside the casing 11.

The LD 12 is a semiconductor element that emits light. The LD 12 is mounted on the element carrier 12a and emits light having a power according to the driving current supplied. The element carrier 12a fixes the LD 12 and is a wiring substrate electrically connecting an electrode of the LD 12. The element carrier 12a is fixed on the stem 14.

The lens 13 transmits the light emitted from the LD 12. For example, the lens 13 is a collimating lens that collimates the light output from the LD 12. The lens 13 outputs the collimated light from the opening lib of the casing 11 to the output unit 16. A lens holder 13a supporting the lens 13 is provided at the lens 13. The lens 13 is fixed on the stem 14 via the lens holder 13a.

The stem 14 is a support member supporting the element carrier 12a and the lens 13. The stem 14 includes a first support 14a, a second support 14b, and an intermediate portion 14c. The first support supports the LD 12. Specifically, the first support 14a has an upper aspect 14A parallel to the yz-plane. The LD 12 is placed on the upper aspect 14A (first support aspect) to be supported.

The second support 14b supports the lens 13. Specifically, the second support 14b has, at a position where the light emitted from the LD 12 is transmitted, a through-hole of a size corresponding to the size of the lens 13 and into which the lens holder 13a is inserted to support the lens 13. The first support 14a and the second support 14b are integrated via the intermediate portion 14c.

Further, a width of the intermediate portion 14c may be smaller than a width of the first support 14a and the second support 14b in at least one direction (a direction on the xy-plane) perpendicular to the orientation of arrangement (direction of the z-axis) of the first support 14a, the intermediate portion 14c, and the second support 14b. In the configuration depicted in FIG. 1, a width of the intermediate portion 14c is smaller than a width of the first support 14a and the second support 14b in the direction of the x-axis.

Thus, thermal conductivity of the intermediate portion 14c can be made lower than the thermal conductivity of the first support 14a and the second support 14b. As a result, heat transferred to the Peltier element 15 from the second support 14b through the intermediate portion 14c can be reduced. Further, though not depicted, the stem 14 may be configured such that a width of the intermediate portion 14c is smaller than a width of the first support 14a and the second support 14b in the direction of the y-axis.

A lower aspect of the Peltier element 15 is in contact with and fixed to an interior wall of the casing 11. Further, an upper aspect of the Peltier element 15 is in contact with and fixed to a lower aspect of the stem 14. The Peltier element 15 dissipates, to the lower aspect in contact with an interior wall of the casing 11, heat of the upper aspect in contact with the stem 14. Thus, heat from the stem 14 is dissipated to the casing 11 and the stem 14 is cooled. By cooling the stem 14, the LD 12 fixed on the stem 14 is cooled.

The output unit 16 is provided at the opening 11b on the external side of the casing 11. The output unit 16 includes an isolator 17, a lens 18, and an optical fiber 19. The isolator 17 transmits the light from the lens 13 to the lens 18. In addition, the isolator 17 blocks light traveling from the lens 18 toward the lens 13. The lens 18 converges, to an end of the optical fiber 19, the light traveling from the lens 13 and through the isolator 17. The optical fiber 19 outputs, to an external destination, the light converged by the lens 18.

Thus, according to the optical semiconductor apparatus 10 of the first embodiment, through integration of the first support 14a and the second support 14b, relative positions of the first support 14a and the second support 14b can be adjusted with high precision by fabrication of the system 14. As a result, the light emitted from the LD 12 can be coupled with the end of the optical fiber 19 with high precision and the transmission characteristics of the light output from the output unit 16 can be improved.

FIG. 3 is a top view of a modified example of the optical semiconductor element depicted in FIGS. 1 and 2. As depicted in FIG. 3, the optical semiconductor element that emits light, i.e., the LD 12 depicted in FIGS. 1 and 2, may be substituted with an LD array 31 having plural LDs. The LDs of the LD array 31 are arrayed in the direction of the y-axis and are fixed to the stem 14 by the element carrier 12a.

In this case, in place of the optical fiber 19 depicted in FIG. 1, an optical fiber array (not depicted) is provided having plural optical fibers arrayed in the direction of the y-axis. Lights emitted from the LD array 31 are respectively coupled to ends of the optical fibers of the optical array and are output to an external destination by the optical fibers.

According to the optical semiconductor apparatus 10, the coupling position of the each of the lights output from the LD array 31 can be adjusted with precision in the direction of the x-axis. Therefore, as depicted by reference numeral 32, respective coupling positions of lights 33 emitted from the LD array 31 are easily aligned in a straight line along the direction of the y-axis. As a result, with precision, each of the lights emitted can be coupled with the ends of the optical fibers of the optical fiber array aligned along the direction of the y-axis. Thus, the respective transmission characteristics of the channels of the optical fiber array can be made uniform.

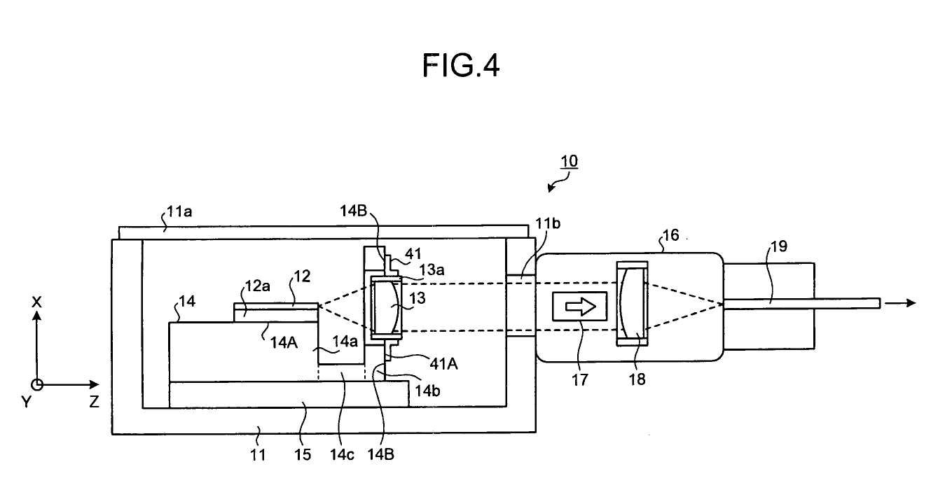

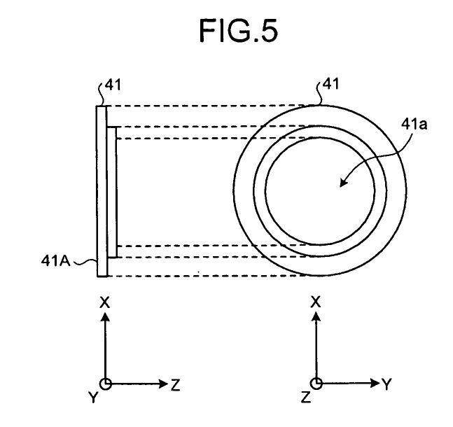

FIG. 4 is a front cross-sectional view of the optical semiconductor apparatus according to a second embodiment. FIG. 5 is a front view and a side view of a fixing ring depicted in FIG. 4. In FIG. 4, components identical to those depicted in FIG. 1 are given identical reference numerals and description thereof is omitted. As depicted in FIG. 4, the optical semiconductor apparatus 10 according to the second embodiment has the configuration of the optical semiconductor apparatus 10 according to the first embodiment with the addition of a fixing ring 41.

The second support 14b includes an aspect 14B (second support aspect) oriented perpendicular to the upper aspect 14A (first support aspect) of the first support 14a on which the LD 12 is placed. The fixing ring 41 is positioning member that holds the lens 13 and positions the lens 13 with respect to the second support 14b. The fixing ring 41 has an aspect 41A that is fixed in contact with the aspect 14B of the second support 14b.

The lens 13 and the lens holder 13a are arranged in a space 41a (refer to FIG. 5) of the fixing ring 41 and are fixed and held by the fixing ring 41. At the time of assembly of the optical semiconductor apparatus 10, the aspect 41A of the fixing ring 41 is not fixed to the aspect 14B of the second support 14b. Thus, the fixing ring 41 is slidable in the direction of the xy-plane.

In this state, the LD 12 is caused to emit light and the light output from the optical fiber 19 is monitored while the fixing ring 41 is slid. The position of the fixing ring 41 with respect to the second support 14b is determined as the position where the monitored light has the greatest power. Thereafter, the aspect 41A of the fixing ring 41 is fixed by, for example, laser welding to the aspect 14B of the second support 14b.

Thus, the lens 13 can be fixed to the second support 14b in a state where the position of the lens 13 on the xy-plane is adjusted with high precision with respect to the light from the LD 12. Here, a configuration in which the LD 12 is provided as an optical semiconductor apparatus that emits light has been described; however, the LD 12 may be substituted with the LD array 31 (refer to FIG. 3). In this case, in place of the optical fiber 19, an optical fiber array having plural optical fibers arrayed in the direction of the y-axis is provided.

Thus, according to the optical semiconductor apparatus 10 of the second embodiment, effects of the optical semiconductor apparatus 10 according to the first embodiment can be achieved and more precise adjustment of the position of the lens 13 on the xy-plane with respect to the light emitted from the LD 12 can be realized by the fixing ring 41. As a result, the light emitted from the LD 12 is coupled with the end of the optical fiber 18 with greater precision and coupling loss of the light output from the output unit 16 can be reduced.

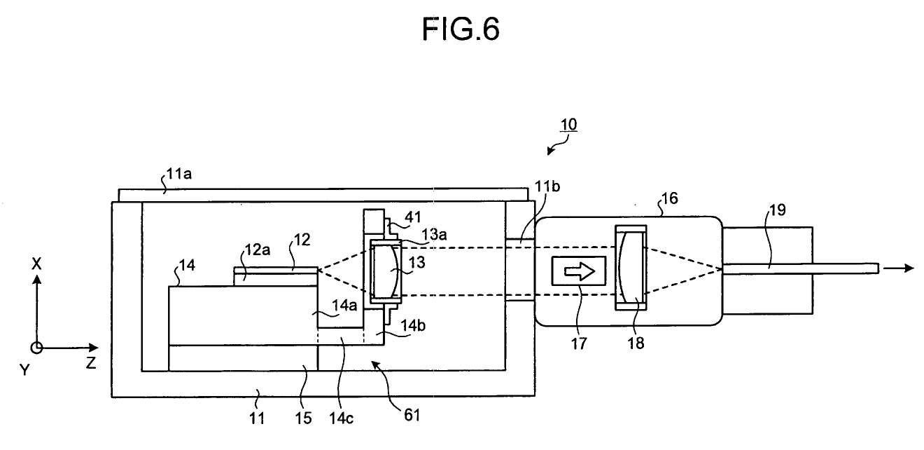

FIG. 6 is a front cross-sectional view of the optical semiconductor apparatus according to a third embodiment. In FIG. 6, components identical to those depicted in FIG. 4 are given identical reference numerals and description thereof is omitted. As depicted in FIG. 6, the optical semiconductor apparatus 10 according to the third embodiment has a configuration in which the portion of the Peltier element 15 depicted in FIG. 4 and positioned at the lower aspect of the second support 14b and the intermediate portion 14c is omitted.

In other words, only the portion of the Peltier element 15 positioned at the lower aspect of the first support 14a is provided. As a result, the Peltier element 15 is provided in contact with the first support 14a and is separate from the second support 14b. Here, although a gap 61 between the second support 14b and the casing 11 is empty, thermal insulation may be provided in the gap 61.

Since the lens 13, the lens holder 13a, the second support 14b, and the fixing ring 41 are provided near the LD 12, heat generated by the LD 12 causes the temperature of these components to rise. However, despite this fundamentally, temperature control for the lens 13, the lens holder 13a, the second support 14b, and the fixing ring 41 is not required. Therefore, if the Peltier element 15 absorbs the heat of these components, the cooling function of the Peltier element 15 is wastefully expended.

With this being the case, by isolating the Peltier element 15 from the second support 14b, the heat of the lens 13, the lens holder 13a, the second support 14b, and the fixing ring 41, whose temperatures that have risen, is not directly transferred to the Peltier element 15. Further, as the width of the intermediate portion 14c in the direction of the x-axis is relatively small compared to the second support 14b, thermal conductivity of the intermediate portion 14c is low. Thus, the heat transferred to the Peltier element 15 from the second support 14b through the intermediate portion 14c can be reduced.

Additionally, in the configuration depicted in FIG. 4, the portion of the Peltier element 15 positioned at the lower aspect of the intermediate portion 14c is omitted here. As a result, heat transferred to the intermediate portion 14c from the second support 14b is not directly transferred to the Peltier element 15; thereby enabling further reduction of the heat transferred to the Peltier element 15 from the second support 14b through the intermediate portion 14c.

Thus, according to the optical semiconductor apparatus 10 of the third embodiment, effects of the optical semiconductor apparatus 10 according to the second embodiment can be achieved and wasteful use of the cooling function of the Peltier element 15 by cooling the lens 14, the second support 14b, etc. can be prevented by isolating the Peltier element 15 from the second support 14b. As a result, the cooling effect of the Peltier element 15 with respect to the LD 12 is improved and power consumption of the Peltier element 15 can be reduced.

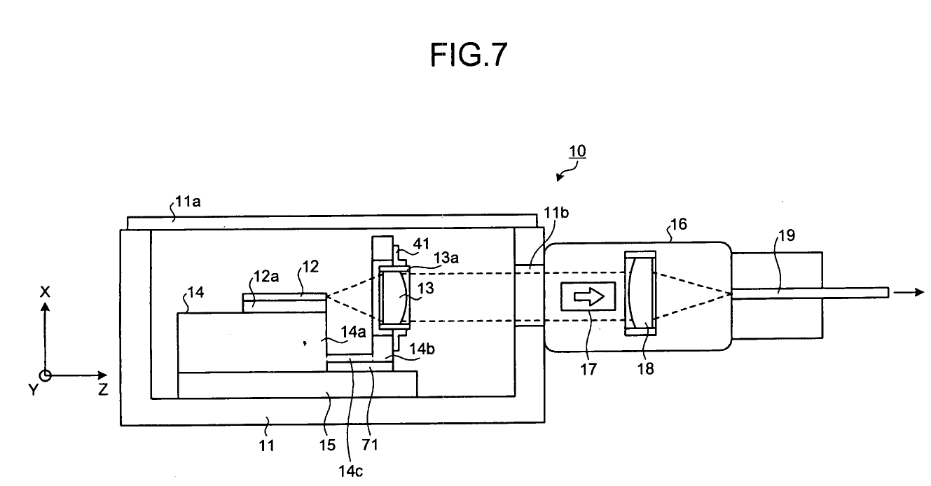

FIG. 7 is a front cross-sectional view of the optical semiconductor apparatus according to a fourth embodiment. In FIG. 7, components identical to those depicted in FIG. 4 are given identical reference numerals and description thereof is omitted. As depicted in FIG. 7, the optical semiconductor apparatus 10 according to the fourth embodiment has a configuration similar to the configuration depicted in FIG. 4; however, the configuration further includes thermal insulation 71 between the Peltier element 15 and the second support 14b.

As a result, the Peltier element 15 is provided in contact with the first support 14a and is thermally isolated from the second support 14b by the thermal insulation 71. Hence, the heat of the lens 13, the lens holder 13a, the second support 14b, and the fixing ring 41, whose temperatures have been raised by the heat generated by the LD 12, is not directly transferred to the Peltier element 15. Therefore, heat transferred to the Peltier element 15 from the second support 14b through the intermediate portion 14c can be reduced.

Additionally, here, the thermal insulation 71 is continuously formed from between the Peltier element 15 and 1) the second support 14b and 2) the intermediate portion 14c. As a result, the Peltier element 15 is also thermally isolated from the intermediate portion 14c. Thus, heat transferred to the intermediate portion 14c from the second support 14b is not directly transferred to the Peltier element 15 and the heat transferred to the Peltier element 15 from the second support 14b can be further reduced.

Thus, according to the optical semiconductor apparatus 10 of the fourth embodiment, effects of the optical semiconductor apparatus 10 according to the second embodiment can be achieved and wasteful use of the cooling function of the Peltier element 15 by cooling the lens 13 and other components can be prevented by thermally isolating the Peltier element 15 from the second support 14b by the thermal insulation 71. As a result, the cooling effect of the Peltier element 15 with respect to the LD 12 is improved and power consumption of the Peltier element 15 can be reduced.

Additionally, unlike the configuration depicted in for example FIG. 6, the Peltier element 15 can be provided beneath the second support 14b and the intermediate portion 14c. As a result, the volume of the Peltier element 15 can be made sufficiently large. Thus, compared to the configuration depicted in for example FIG. 6, the cooling function of the Peltier element 15 can be improved.

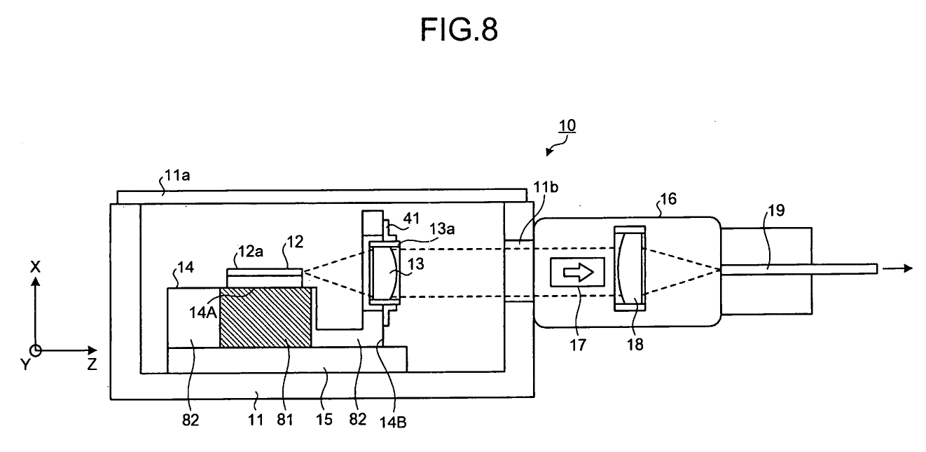

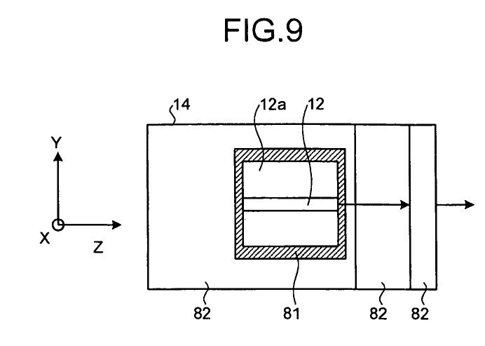

FIG. 8 is a front cross-sectional view of the optical semiconductor apparatus according to a fifth embodiment. FIG. 9 is a top view of the optical semiconductor element and the stem depicted in FIG. 8. In FIGS. 8 and 9, components identical to those depicted in FIG. 4 are given identical reference numerals and description thereof is omitted. Additionally, although reference numerals are not depicted here, similar to the configuration depicted in FIG. 4, the stem 14 includes the first support 14a, the second support 14b, and the intermediate portion 14c.

As depicted in FIG. 8, the optical semiconductor apparatus 10 according to the fifth embodiment has a configuration similar to the configuration depicted in FIG. 4; however, the stem 14 further includes a first structural portion 81 and a second structural portion 82. The first structural portion 81 is a part that includes the upper aspect 14A depicted in FIG. 4. Further, a lower aspect of the first structural portion 81 is in contact with the Peltier element 15. The second structural portion 82 includes the aspect 14B depicted in FIG. 4 and encompasses the first structural portion 81. The thermal conductivity of the first structural portion 81 is higher than that of the second structural portion 82.

By raising the thermal conductivity of the first structural portion 81, the heat generated by the LD 12 is efficiently transferred to the Peltier element 15 via the first structural portion 81 and the cooling effect of the Peltier element 15 with respect to the LD 12 can be improved. Further, by setting a low thermal conductivity for the second structural portion 82, the Peltier element 15 becomes thermally isolated from the lens 13, the lens holder 13a, and the fixing ring 41 via the second support 14b.

As a result, the heat of the lens 13, the lens holder 13a, and the fixing ring 41, whose temperatures have been raised by the heat generated by the LD 12, is not directly transferred to the Peltier element 15. Therefore, the heat transferred to the Peltier element 15 from the lens 13 and other components can be reduced and wasteful use of the cooling function of the Peltier element 15 by cooling the lens 13 and other components can be prevented.

Furthermore, by setting a low thermal conductivity for the second structural portion 82, the fixing ring 41 can be easily fixed to the aspect 14B by laser welding. Preferably, the coefficient of thermal expansion of the first structural portion 81 is substantially equivalent to that of the second structural portion 82. Specifically, the coefficient of thermal expansion of the first structural portion 81 is preferably at least half and not more than twice that of the second structural portion.

For example, the first structural portion 81 is fabricated of kovar (coefficient of thermal expansion: 3.2×10⁻⁶/K) and the second structural portion 82 is fabricated of Pyrex glass (coefficient of thermal expansion: 4.8×10⁻⁶/K). Thus, even if the first structural portion 81 and the second structural portion 82 thermally expand from the heat generated by the LD 12, the first structural portion 81 and the second structural portion 82 expand at a comparable rate and hence, deviation of the respective positions of the aspect 14A supporting the LD 12 and the aspect 14B supporting the lens 13 can be prevented.

For example, a through-hole of a shape corresponding to the first structural portion 81 is provided in the Pyrex glass forming the second structural portion 82 and kovar forming the first structural portion 81 is inserted in the through-hole provided. Thus, the Pyrex glass and the kovar are integrated to form the stem 14. Further, after the kovar is inserted into the Pyrex glass, by removing any unevenness between the Pyrex glass and the kovar by polishing, etc., relative positions of the aspect 14A supporting the LD 12 and the aspect 14B supporting the lens 13 can be determined with great precision.

Thus, according to the optical semiconductor apparatus 10 of the fifth embodiment, effects of the optical semiconductor apparatus 10 according to the second embodiment can be achieved and by configuring the stem 14 of the first structural portion 81 having a high thermal conductivity and the second structural portion having a low thermal conductivity, the cooling effect of the Peltier element 15 with respect to the LD 12 is improved and power consumption of the Peltier element 15 can be reduced. Additionally, by setting a low thermal conductivity for the second structural portion 82, the fixing ring 41 can be easily fixed to the aspect 14B by laser welding.

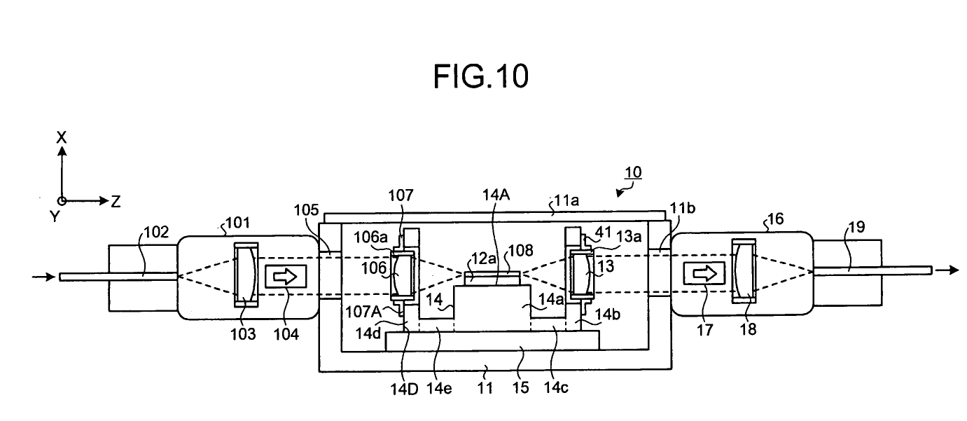

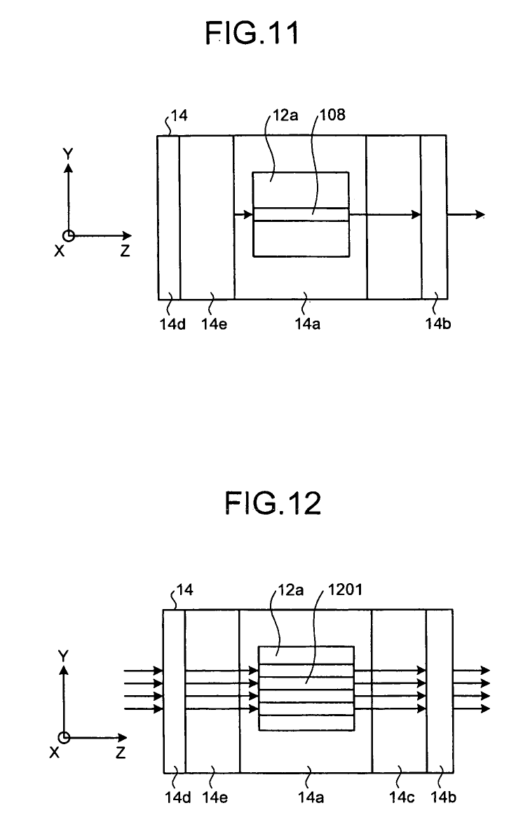

FIG. 10 is a front cross-sectional view of the optical semiconductor apparatus according to a sixth embodiment. FIG. 11 is a top view of the optical semiconductor element and the stem depicted in FIG. 10. In FIG. 10, components identical to those depicted in FIG. 4 are given identical reference numerals and description thereof is omitted. The optical semiconductor apparatus 10 according to the sixth embodiment is an amplifying apparatus that amplifies and outputs light input thereto.

As depicted in FIG. 10, the optical semiconductor apparatus 10 has the configuration depicted in FIG. 4 with the addition of an input unit 101, a lens 106 (second lens), and a fixing ring 107. Further, in place of the LD 12 depicted in FIG. 4, an SOA 108 is provided. The SOA 108 amplifies an optical signal input thereto from the lens 106 and outputs the optical signal to the lens 13. An opening 105 for the input of light is provided in the casing 11.

The input unit 101 is provided at the opening 105 on the external side of the casing 11. The input unit 101 includes an optical fiber 102, a lens 103, and an isolator 104. An optical signal from an external source is input to the optical fiber 102. The optical fiber 102 outputs the optical signal input thereto to the lens 103. The lens 103 collimates the optical signal output from the optical fiber 102 and outputs the collimated optical signal to the isolator 104.

The isolator 104 transmits the optical signal output from the lens 103 to the lens 106. In addition, the isolator 104 blocks light traveling from the lens 106 toward the lens 103. The lens 106 converges the optical signal output from the isolator 104 and inputs the converged light to the SOA 108. A lens holder 106a supporting the lens 106 is provided at the lens 106. The lens 106 is fixed held by the lens holder 106a.

The stem 14 is a support member supporting the SOA 108, the lens 13, and the lens 106. The stem 14 includes the first support 14a, the second support 14b, the intermediate portion 14c, a third support 14d, and a second intermediate portion 14e. The third support 14d is provided on a side opposite of the second support 14b of the stem 14. The first support 14a and the third support 14d are integrated via the second intermediate portion 14e.

In other words, the first support 14a, the second support 14b, the intermediate portion 14c, the third support 14d, and the second intermediate portion 14e are integrated. The third support 14d supports the lens 106. Specifically, the third support 14d has, at a position where light output from the isolator 104 is transmitted, a through-hole of a size corresponding to the lens 106 and into which the lens 106 is inserted to support the lens 106.

The third support 14d has an aspect 14D oriented perpendicular to the upper aspect 14A of the first support 14a where the SOA 108 is placed. The fixing ring 107 is positioning member that holds the lens 106 and positions the lens 106 with respect to the third support 14d. The shape of the fixing ring 107 is identical to that of the fixing ring 41 (refer to FIG. 5). The fixing ring 107 has an aspect 107A that is fixed in contact with the aspect 14D of the third support 14d.

The lens 106 and the lens holder 106a are arranged in an opening of the fixing ring 107 and, are fixed and held by the fixing ring 107. At the time of assembly of the optical semiconductor apparatus 10, the aspect 107A of the fixing ring 107 is not fixed to the aspect 14D of the third support 14d. Thus, the fixing ring 107 is slidable in the direction of the xy-plane. In this state, the light from the optical fiber 102 is input, the SOA 108 is operated, and the light output from the optical fiber 19 is monitored while the fixing ring 107 is slid with respect to the third support 14d.

The position of the fixing ring 107 with respect to the third support 14d is determined as the position where the monitored light has the greatest power. Thereafter, the aspect 107A of the fixing ring 107 is fixed by, for example, laser welding to the aspect 14D of the third support 14d. As a result, the lens 106 can be fixed to the third support 14d in a state where the position of light output from the lens 106 on the xy-plane is adjusted with high precision with respect to the input unit of the SOA 108.

Thus, according to the optical semiconductor apparatus 10 of the sixth embodiment, effects of the optical semiconductor apparatus 10 according to the fourth embodiment can be achieved and through integration of the first support 14a and the third support 14d, relative positions of the first support 14a and the third support 14d can be adjusted with high precision through fabrication of the stem 14. As a result, the light input from the optical fiber 102 can be input to the SOA 108 with high precision and the transmission characteristics of the light output from the SOA 108 can be improved.

FIG. 12 is a top view of a modified example of the optical semiconductor element depicted in FIGS. 10 and 11. As depicted in FIG. 12, the SOA 108 depicted in FIGS. 10 and 11 may be substituted with an SOA array 1201 having plural SOAs. The SOAs of the SOA array 1201 are arrayed in the direction of the y-axis and are fixed to the stem 14 by the element carrier 12a.

In this case, in place of the optical fiber 102 depicted in FIG. 10, an optical fiber array (not depicted) is provided having plural optical fibers arrayed in the direction of the y-axis. Each of the optical fibers of the optical fiber array is input with light from an external source. The lights respectively input to the optical fibers of the optical fiber array are input to the SOAs of the SOA array 1201.

Additionally in this case, in place of the optical fiber 19 depicted in FIG. 10, an optical fiber array (not depicted) is provided having plural optical fibers arrayed in the direction of the y-axis. The lights output from the SOA array 1201 are respectively coupled to the ends of the optical fibers of the optical fiber array and are output to an external destination by the optical fibers.

According to the optical semiconductor apparatus 10, the coupling position of the lights output from the SOA array 1201 can be adjusted with precision in the direction of the x-axis. Therefore, respective coupling positions of lights output from the SOA array 1201 are easily aligned in a straight line along the direction of the y-axis. As a result, with precision, each of the lights output can be coupled with the ends of the optical fibers of the optical fiber array aligned along the direction of the y-axis. Thus, the respective transmission characteristics of the channels of the optical fiber array can be improved.

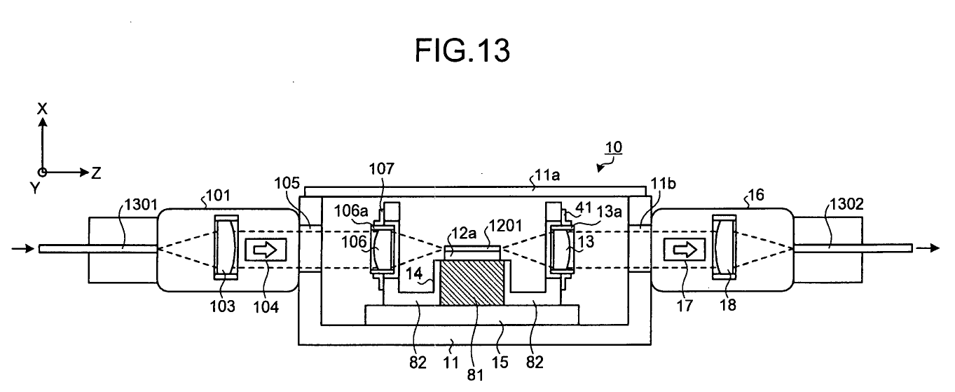

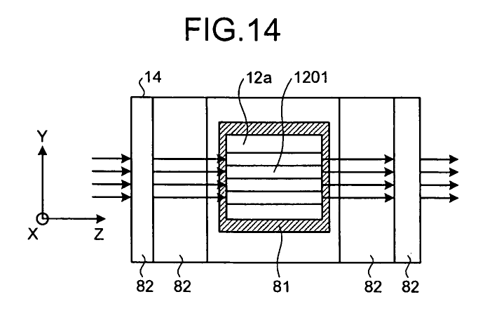

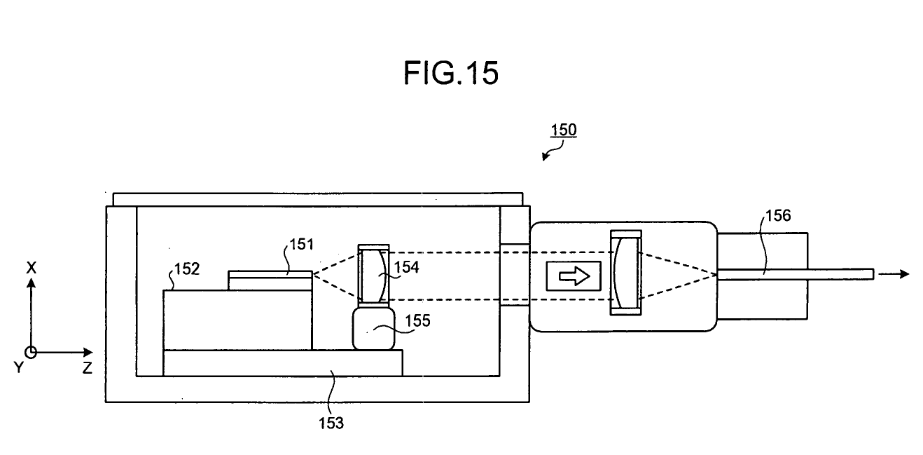

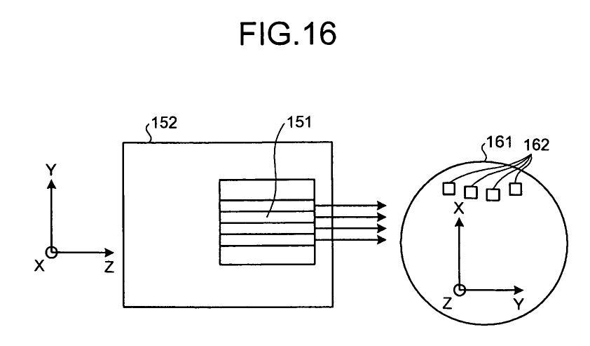

FIG. 13 is a front cross-sectional view of the optical semiconductor apparatus according to a seventh embodiment. FIG. 14 is a front view and a side view of an optical semiconductor element and a stem depicted in FIG. 13. In FIG. 13, components identical to those depicted in FIG. 8 or FIG. 10 are given identical reference numerals and description thereof is omitted. Further, the stem 14 includes the first support 14a, the second support 14b, the intermediate portion 14c, the third support 14d, and the second intermediate portion 14e although reference numerals thereof are not depicted.

As depicted in FIGS. 13 and 14, the optical semiconductor apparatus 10 according to the seventh embodiment has a configuration similar to the configuration depicted in FIG. 10; however, the stem 14 further includes the first structural portion 81 and the second structural portion 82. Here, the second structural portion 82 includes both the aspect 14B and the aspect 14D depicted in FIG. 10, and encompasses the first structural portion 81. As descriptions of the first structural portion 81 and the second structural portion 82 are identical to the descriptions given with respect to FIGS. 8 and 9, description herein is omitted.

Here, in place of the SOA 108 depicted in FIG. 10, the SOA array 1201 (refer to FIG. 12) is provided. Further, in place of the optical fiber 102 depicted in FIG. 10, an optical array 1301 is provided having plural optical fibers arrayed in the direction of the y-axis. Light from an external source is input to each of the optical fibers of the optical fiber array 1301. The light input from the optical fibers is input to each of the SOAs of the SOA array 1201.

Further, in this case, in place of the optical fiber 19 depicted in FIG. 10, an optical fiber array 1302 is provided having plural optical fibers arrayed in the direction of the y-axis. The lights output from the SOA array 1201 are coupled respectively with the ends of the optical fibers of the optical fiber array 1302 and are output to an external destination by the optical fibers.

Thus, according to the optical semiconductor apparatus 10 of the seventh embodiment, effects of the optical semiconductor apparatus 10 according to the sixth embodiment can be achieved and by configuring the stem 14 of the first structural portion 81 having a high thermal conductivity and the second structural portion having a low thermal conductivity, the cooling effect of the Peltier element 15 with respect to the SOA array 1201 is improved and power consumption of the Peltier element 15 can be reduced. Additionally, by setting a low thermal conductivity for the second structural portion 82, the fixing ring 41 can be easily fixed to the aspect 14B by laser welding. Additionally, the fixing ring 107 can be easily fixed to the aspect 14D by laser welding.

As set forth above, according to the configuration above, through integration of the first support and the second support, respective positions of the first support supporting the optical semiconductor element and the second support supporting the lens can be adjusted with high precision by fabricating a member that determines the relative positions.

As described above, according to the optical semiconductor apparatus disclosed, transmission characteristics of output light can be improved.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. An optical semiconductor apparatus comprising:
an optical semiconductor element that outputs light;
a lens that transmits light output from the optical semiconductor element; and
a support member that is integrally formed and includes a first support supporting the optical semiconductor element, a second support supporting the lens, and an intermediate portion through which the first support and the second support are integrated.

2. The optical semiconductor apparatus according to claim 1, wherein
the first support includes a first support aspect supporting the optical semiconductor element and where the optical semiconductor element is placed,
the second support includes a second support aspect oriented perpendicular to the first support aspect, and
the optical semiconductor apparatus further comprises a member that holds the lens, includes an aspect fixed in contact with the second support aspect, and positions the lens.

3. The optical semiconductor apparatus according to claim 1, further comprising a Peltier element provided in contact with the first support and isolated from the second support.

4. The optical semiconductor apparatus according to claim 3, further comprising thermal insulation provided between the Peltier element and the second support.

5. The optical semiconductor apparatus according to claim 1, further comprising a Peltier element provided in contact with the support member, wherein
the support member includes:
a first structural portion in contact with the Peltier element, and having a first support aspect supporting the optical semiconductor element and where the optical semiconductor element is placed,
a second structural portion encompassing the first structural portion and having a second support aspect supporting the lens, and
the first structural portion has a thermal conductivity that is higher than a thermal conductivity of the second structural portion.

6. The optical semiconductor apparatus according to claim 5 wherein the first structural portion has a coefficient of thermal expansion that is substantially equivalent to a coefficient of thermal expansion of the second structural portion.

7. The optical semiconductor apparatus according to claim 5 wherein the first structural portion has a coefficient of thermal expansion that is at least half and less than twice a coefficient of thermal expansion of the second structural portion.

8. The optical semiconductor apparatus according to claim 5 wherein the first structural portion is fabricated of kovar and the second structural portion is fabricated of Pyrex glass (registered trade name).

9. The optical semiconductor apparatus according to claim 1, wherein the optical semiconductor element is provided in plural arrayed at the first support.

10. The optical semiconductor apparatus according to claim 1, wherein the optical semiconductor element is a laser diode outputting light according to a supplied driving current.

11. The optical semiconductor apparatus according to claim 1, further comprising a second lens transmitting the light and inputting the light to the optical semiconductor element, wherein
the optical semiconductor element is a semiconductor optical amplifier amplifying the light input by the second lens, and
the support member includes a third support supporting the second lens and integrated with the first support through a second intermediate portion.

12. The optical semiconductor apparatus according to claim 1, wherein the intermediate portion has a width smaller than a width of the first support and the second support in at least one direction perpendicular to an orientation of arrangement of the first support, the intermediate portion, and the second support.
